(19) United States
(12) Patent Application Publication
(10) Pub. No.: US 2023/0051254 A1
(43) Pub. Date: Feb. 16, 2023

(54) DEVICE FOR COOLING A BATTERY PACK

(71) Applicant: Valeo Systemes Thermiques, Le Mesnil Saint-Denis (FR)

(72) Inventors: Kamel Azzouz, Le Mesnil Saint Denis (FR); Sébastien Garnier, Le Mesnil Saint Denis (FR); Amrid Mammeri, Le Mesnil Saint Denis (FR)

(73) Assignee: Valeo Systemes Thermiques, Le Mesnil Saint-Denis (FR)

(21) Appl. No.: 17/784,821

(22) PCT Filed: Dec. 11, 2020
(86) PCT No.: PCT/FR2020/052400

§ 371 Date: Jun. 13, 2022

(30) Foreign Application Priority Data
Dec. 12, 2019 (FR) FR1914325

(51) Int. Cl. H05K 7/20; H01M 10/613; H01M 10/625; H01M 10/63; H01M 10/647; H01M 10/6568; H01M 10/6569; H01M 50/209; G05D 16/20; B60L 58/26

(52) U.S. Cl. CPC H05K 7/20345; H01M 10/613; H01M 10/625; H01M 10/63; H01M 10/647; H01M 10/6568; H01M 10/6569; H01M 50/209; G05D 16/2006; H05K 7/20327; H05K 7/208; B60L 58/26; H01M 2220/20

(57) ABSTRACT

The invention relates to a device (2) for cooling a plurality of electronic elements (11) that are capable of releasing heat when supplying power to an appliance or vehicle, wherein the electronic elements are arranged in a housing (12), the device (2) comprises at least one element (22) for spraying a diphasic dielectric fluid (3) onto the electronic elements (11), as well as a condenser (26) with a cooling fluid circuit (23), the housing (12) comprises a receptacle (25) for collecting the dielectric fluid (3), the cooling device (2) comprises a dielectric fluid circuit (21) with a circulation pump (24), which is configured to draw the dielectric fluid (3) from the collection receptacle (25) and is directly connected to the spraying element (22), characterised in that the cooling device (2) comprises a system (4) for controlling the internal pressure of the housing (12), the control system (4) comprising a control module (41) configured to generate a control command to control the internal pressure depending on a state of the cooling device and/or a state of the appliance or vehicle.

The present invention relates to the field of devices for cooling electronic elements and it may concern in particular devices for cooling battery packs of a hybrid or electric motor vehicle.

The industrial market involving the use of electronic elements that are capable of releasing significant heat during operation, for example in the field of the hybrid or electric motor vehicle industry, is increasingly large. In particular, hybrid or electric motor vehicles are powered by rechargeable electric batteries which, in operation, can reach extreme temperatures, these temperatures being able to generate a risk of damage to the structures of the vehicle in the vicinity of the batteries, and/or a risk of the batteries catching fire or at the very least operating less well.

It is known practice to group the batteries of a hybrid or electric vehicle together within a battery pack and to use an element for spraying a fluid onto them in order to cool them, the fluid being dielectric so as not to short-circuit the batteries. The latter are thus kept at a sufficiently low temperature to reduce the abovementioned risks.

The dielectric fluid may in particular by a two-phase fluid which, upon contact with the batteries and by exchange of heat energy, passes into the vapor state. It is therefore known practice to equip the battery pack with a condenser, in order to return the dielectric fluid into the liquid state. The dielectric fluid in the liquid state is then collected, in particular at the bottom of the battery pack, and can for example be directed to a network of recirculation channels in order to be reintroduced into the battery pack so as to be sprayed onto the batteries during a subsequent use.

The above explanation applies when the vehicle is in operation. A similar problem arises when the vehicle is parked. Specifically, under the effect of the still hot batteries, or under summery weather conditions, the dielectric fluid can pass into the vapor state and increase the pressure in the housing containing the batteries. An excessive internal pressure in the housing causes the dielectric fluid in the vapor state to leak and therefore to be lost.

The present invention makes it possible to remedy the problem of evaporation of the dielectric fluid within a housing containing electric batteries, despite the vehicle being stopped.

Thus the invention consists of a device for cooling a plurality of electronic elements that are capable of releasing heat during operation for supplying electrical power to an apparatus or vehicle, said electronic elements being disposed in a housing, the device comprising at least one element for spraying a two-phase dielectric fluid onto the electronic elements, and a condenser provided with a cooling fluid circuit, the housing comprising a tank for collecting the dielectric fluid, the cooling device comprising a dielectric fluid circuit, which is provided with a circulation pump configured to draw the dielectric fluid from the collecting tank and is directly connected to the spraying element, characterized in that the cooling device comprises a system for regulating the internal pressure in the housing, the regulating system comprising a control module configured to generate a control instruction for regulating the internal pressure depending on a state of the cooling device and/or a state of the apparatus or vehicle.

The spraying element is configured to spray the two-phase dielectric fluid, in the liquid state, onto the electronic elements. Exchange of heat energy then takes place between the hot electronic elements and the dielectric fluid, which evaporates under the effect of the high temperature of the electronic elements. The latter may be, for example, battery cells for a hybrid or electric vehicle, or any other electronic element that can reach very high temperatures and needs to be cooled as a result.

The condenser may be, for example, in the form of a metal plate within which a cooling fluid circulates. The condenser is disposed within the housing such that contact is created between the condenser and the dielectric fluid in the form of vapor. A new exchange of heat energy is brought about between the dielectric fluid in the form of vapor and the condenser associated with the cooling fluid, thereby allowing the dielectric fluid to give off the heat previously acquired and to return to the liquid state. The housing is configured such that this two-phase electric fluid in the liquid state flows as far as the collecting tank.

The dielectric fluid circuit connects the collecting tank to the spraying element in order for it to be possible to spray the dielectric fluid in the form of liquid onto the electronic elements again. The circulation pump makes it possible to draw out the dielectric fluid present in the collecting tank and to make it circulate within the dielectric fluid circuit. The dielectric fluid circuit may open out directly at the spraying element, or, for example, pass through the condenser before opening out at the spraying element, in order to lower the temperature of the dielectric fluid before it is sprayed onto the electronic elements and can thus bring about more effective cooling of the latter.

The pressure regulating system of the cooling device is configured to avoid an overpressure in the housing, which may cause stresses at the joints of this housing and possibly leaks of dielectric fluid. Such an overpressure is caused in particular by the evaporation of the dielectric fluid present in the housing and in particular when the vehicle is stopped and when the cooling device is not in operation, i.e. when the cooling fluid is not circulating in the condenser. This evaporation may take place after the vehicle has been stopped if the temperature reached by the electronic elements situated in the vicinity of the collecting tank remains too high, or generally when the ambient temperature is high.

According to the invention, the control module present within the pressure regulating system makes it possible to detect an increase in internal pressure in the housing, or some other event that may bring about an increase in internal pressure in the housing. The control module also makes it possible, following this detection, to generate a control instruction intended for other components of the pressure regulating system that are able to bring about a reduction in the internal pressure in the housing.

According to one feature of the invention, the control module comprises a pressure sensor, the control module being configured to generate a control instruction for regulating the internal pressure in the housing when a value measured by the pressure sensor exceeds a threshold pressure value. The pressure sensor is advantageously disposed in the housing so as to measure the pressure precisely. The pressure sensor and the control module are configured to communicate with one another, if necessary via wired means.

According to one feature of the invention, the threshold pressure value at which the pressure values measured by the pressure sensor are compared is 1.5 bar. The inventors have found that, starting from this pressure value of 1.5 bar, the internal pressure risks deforming the housing and there is then a risk of the dielectric fluid present in the housing escaping from the housing, this pressure corresponding to a temperature of around 48° C. The control module collects, in real time, or at regular intervals, the pressure values measured by the pressure sensor and initiates the pressure regulation, that is to say generates appropriate control instructions, when one of the pressure values collected is greater than or equal to 1.5 bar.

According to one feature of the invention, the control module initiates regulation of the internal pressure by generating a control instruction intended for the cooling fluid circuit associated with the condenser. In other words, the control module controls the starting up of the cooling fluid circuit only when the threshold pressure value has been reached.

The regulation of the internal pressure in the case that has just been set out, with control of the internal pressure and a control instruction relating to this pressure control, is said to be active, meaning that the regulation is carried out in real time depending on an excessive pressure being measured.

According to one feature of the invention, the cooling device has a detector for detecting the state of the apparatus or vehicle, which is capable of detecting and sending to the control module information relating to the stopping or operation of the apparatus or vehicle. A detector for detecting the state of the apparatus or vehicle should be understood as being a sensor which detects whether the apparatus or vehicle on which the cooling device is installed is operating or is stopped. For example, the state detector may, for example, be an accelerometer or a member directly connected to the vehicle starter device. The detector for detecting the state of the apparatus or vehicle may send a signal to the control module as soon as the change in state has been established, whether this be, for example, stopping of contact with the vehicle or starting of the latter.

According to one feature of the invention, the pressure regulating system comprises a storage reservoir insulated from the housing, and a regulating pump that is able to draw the dielectric fluid present in the collecting tank as far as the storage reservoir and/or to draw the dielectric fluid present in the storage reservoir as far as the collecting tank, depending on an indication provided by the detector for detecting the state of the apparatus or vehicle. In other words, the pressure regulating system may be configured to ensure the transfer of the dielectric fluid between the collecting tank and the storage reservoir, in both directions of circulation depending on the state of the vehicle determined via the detector for detecting the state of the vehicle. More particularly, when the motor of the vehicle is not turning and the cooling fluid is not circulating in the condenser, the risk of the dielectric fluid heating up is high, and the regulating system is configured to withdraw the dielectric fluid from the housing of the cooling device.

Thus, when it is detected that the vehicle is stopped, the motor is cut for example, the detector for detecting the state of the vehicle transmits the information to the control module, which initiates the operation of the regulating pump in order to transfer the dielectric fluid from the collecting tank to the storage reservoir. Conversely, when the vehicle is started up, the dielectric fluid is transferred in the opposite direction, that is to say from the storage reservoir to the collecting tank, in order that the dielectric fluid is once again present in the housing in order to play its part of cooling the batteries.

Drawing the dielectric fluid out of the collecting tank, and therefore out of the housing, makes it possible to avoid evaporation of the two-phase dielectric fluid within the housing when the vehicle is stopped, for example under the effect of the electronic elements, for example battery elements, that may remain at a high temperature, or under the effect of summery weather conditions. Thus, the regulating system may also comprise a temperature sensor that measures the ambient temperature of the outside environment and/or the temperature within the housing, in order to determine whether it is necessary to pump the dielectric fluid out of the housing or not, this temperature information being able in particular to be considered in addition to that of the stopping of the vehicle.

The regulation of the internal pressure in the case that has just been set out, with removal of the dielectric fluid from the housing to avoid an overpressure if the vehicle is stopped, is said to be passive, meaning that the dielectric fluid is evacuated from the collecting tank as soon as the vehicle is stopped, in order to prevent a potential increase in the internal pressure in the housing, without the internal pressure in the housing being otherwise certain to increase excessively.

According to one feature of the invention, the regulating system comprises an insulating structure covering the storage reservoir. The insulating structure is independent of the housing, remote therefrom, and covers the storage reservoir. In accordance with the above in the case of a storage reservoir, the dielectric fluid is withdrawn from the housing of the cooling device in order to be taken away from the electronic elements that are capable of bringing about the evaporation of the dielectric fluid. The insulating structure then acts as a thermal barrier in order that the ambient temperature is not capable of bringing about the evaporation of the dielectric fluid either. Under these conditions, the dielectric fluid is kept in the liquid state in order to be operational during its transfer to the housing, and, for example, the collecting tank, when the vehicle is restarted.

According to one feature of the invention, the storage reservoir comprises a heat exchanger. The dielectric fluid can thus be cooled when it is stored within the storage reservoir. The latter may, for example, be passed through by a channel within which a cooling fluid circulates, in order to keep the dielectric fluid at a low temperature. The dielectric fluid is thus kept in a liquid phase. Such a feature may be an alternative, or, by contrast, be employed in a complementary manner, to the presence of an insulating structure as mentioned above.

The invention also covers a method for implementing a cooling device as described above, characterized in that it comprises:
a step of determining, via the control module, at least one piece of data linked to a potential or effective increase in the internal pressure in the housing of the cooling device,
a step of controlling the pressure regulating system to reduce the internal pressure in the housing, the control step being initiated on the basis of said data.

The determining step may in particular involve a measurement taken by a pressure sensor or a temperature sensor, depending on the embodiments of the cooling device, and/or the detection of a state of the vehicle, which detects the stopping or starting of the vehicle. The control module receives one or more signals and generates a control instruction as a result, namely the activation of the cooling fluid circuit when the vehicle is stopped and the internal pressure exceeds a threshold value in the case of active regulation, or the drawing of the dielectric fluid from the collecting tank to the storage reservoir in the case of passive regulation.

The invention also covers a thermal management system comprising a housing intended to receive a plurality of electronic elements that are capable of releasing heat during operation and a cooling device as described above.

The invention also covers a battery pack comprising a plurality of electronic elements that are capable of releasing heat during operation, a housing receiving said electronic elements and a cooling device as described above. Such a battery pack makes it possible to power for example an electric or hybrid motor of a motor vehicle.

Further features, details and advantages of the invention will become more clearly apparent from reading the detailed description given below, by way of nonlimiting indication, with reference to the appended schematic drawings, in which:

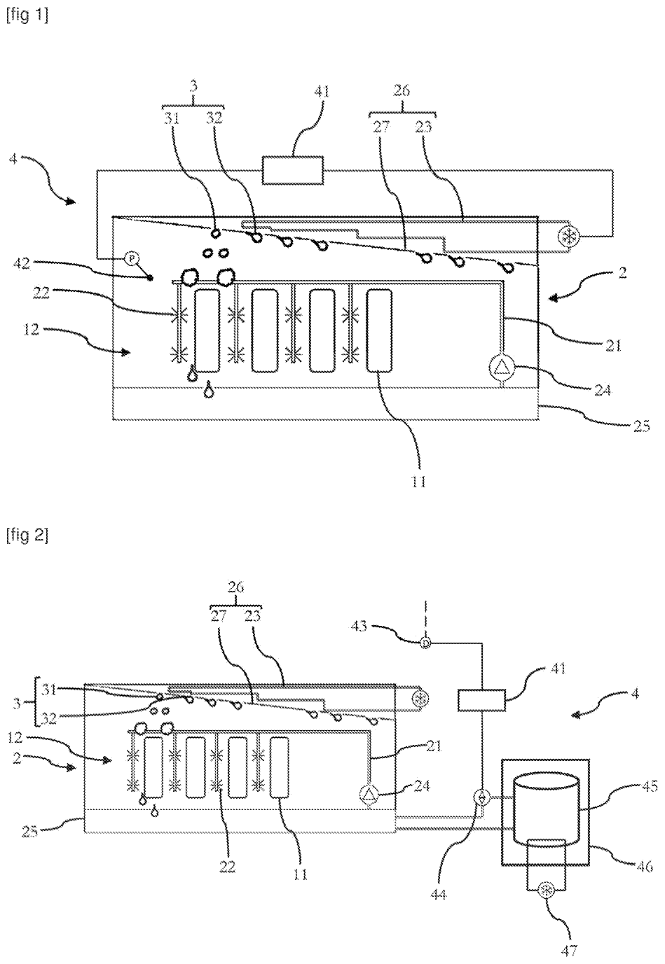

FIG. 1 is a diagram of a first embodiment of a device for cooling electronic elements according to the invention,

FIG. 2 is a diagram of a second embodiment of a device for cooling electronic elements according to the invention,

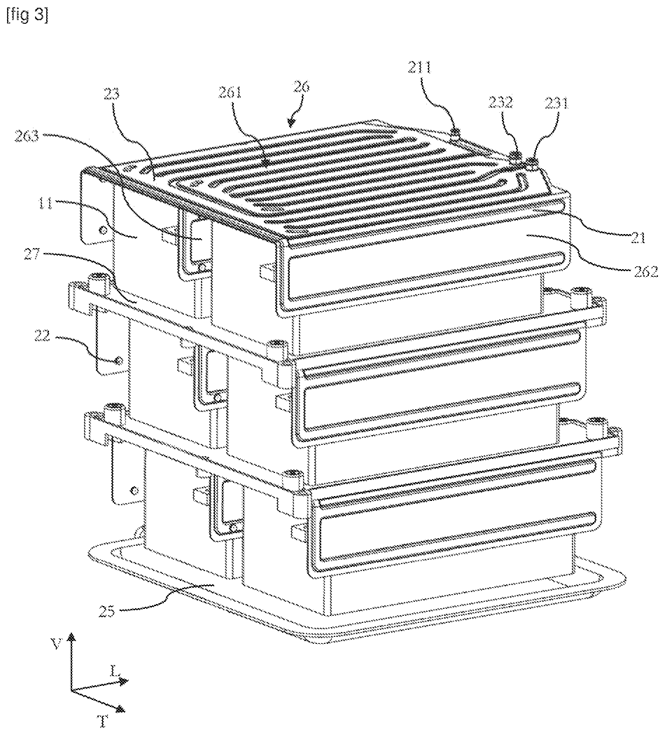

FIG. 3 is a depiction of an example of the contents of a housing of the cooling device,

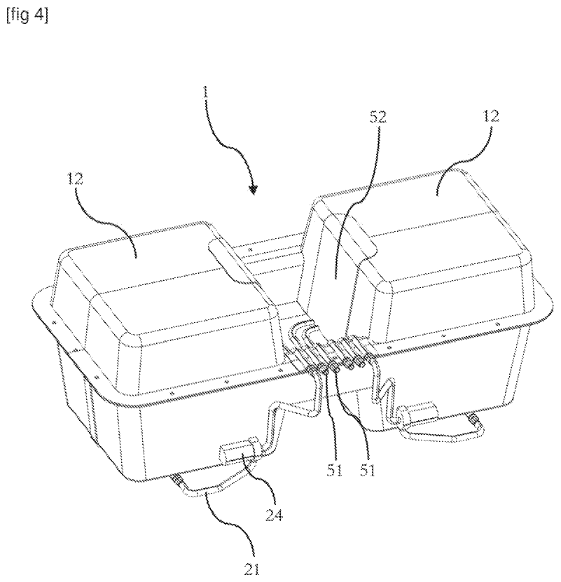

FIG. 4 is a depiction of a battery pack provided with the cooling device according to the invention.

A cooling device 2 according to the invention is illustrated in FIG. 1. Such a device has in particular a housing 12 that accommodates a plurality of electronic elements 11 and a cooling device 2 which comprises at least one dielectric fluid circuit 21 within which a dielectric fluid 3, in this case a two-phase dielectric fluid, circulates and which is configured to allow the cooling of the electronic elements. According to the invention, and as will be described below, the cooling device has a system for regulating the internal pressure in the housing.

The dielectric fluid circuit 21 is in the form of a circulation channel in which at least one spraying element 22 is disposed. The spraying element 22 may, for example, be a spray nozzle for spraying the dielectric fluid 3 in the form of a spray. Advantageously, the dielectric fluid circuit 21 has a plurality of spraying elements 22 distributed so as to spray the dielectric fluid 3 onto a plurality of electronic elements 11.

The electronic elements 11 may, for example, by battery cells for powering an electric or hybrid motor of a vehicle, or computer servers that need to be regularly cooled. In each of these cases, the action of spraying the dielectric fluid 3 onto the electronic elements 11 makes it possible to lower the temperature thereof. FIG. 1 shows four electronic elements 11 onto which dielectric fluid 3 is sprayed via four sets of two spraying elements 22 disposed on the dielectric fluid circuit 21.

Once sprayed onto the electronic elements 11, the two-phase dielectric fluid 3, under the effect of the high temperature of the electronic elements 11, is at least mostly evaporated, vapor phase 31. However, it is possible for a part of the dielectric fluid 3 to remain in the liquid phase despite the exchange of heat with the electronic elements 11. The dielectric fluid 3 in the liquid phase then flows as far as a collecting tank 25 situated below the electronic elements 11. The collecting tank 25 may be in the form of any kind of container that is provided with an internal volume and is able to collect all of the dielectric fluid 3 in the form of a liquid.

The cooling device 2 comprises a condenser 26 which consists of a plate within which a cooling fluid circuit 23 extends. The cooling fluid may, for example, be glycol water, or other refrigerants of the R134a or 1234yf type. The plate forming a condenser 26 has a contact wall 27 that faces toward the inside of the housing and is therefore disposed between the cooling fluid circuit 23 and the spraying element 22. The two-phase dielectric fluid 3, once evaporated by the release of heat from the electronic elements 11, comes into contact with the condenser 26, more specifically with the contact wall 27, and liquefies in contact with this wall cooled under the effect of the cooling fluid circulating in the cooling fluid circuit 23.

In the example illustrated, the contact wall 27 is slightly inclined, thereby making it possible to make the dielectric fluid 3 returned to the liquid form 32 to travel along the contact wall 27 so as to drop into the collecting tank 25 under the effect of gravity. The collecting tank 25 therefore collects the dielectric fluid 3 in the form of a liquid, whether this be two-phase dielectric fluid that has not evaporated while being sprayed onto the electronic elements 11 or fluid that has evaporated and then been liquefied by the condenser 26.

The dielectric fluid circuit 21 comprises an end, opposite to the end comprising the spraying element 22, which is immersed in the dielectric fluid 3 in the form of a liquid 32 that is present in the collecting tank 25. The dielectric fluid circuit 21 is able to draw out the dielectric fluid 3 present in the collecting tank 25 via a circulation pump 24. The dielectric fluid 3 collected in the tank in the form of a liquid can thus recirculate within the dielectric fluid circuit 21 and be sprayed once again onto the electronic elements 11 via the spraying element 22.

In the example illustrated in FIG. 1, the dielectric fluid circuit 21 is insulated from the condenser 26, but it is possible to pass the dielectric fluid circuit 21 through the condenser 26 in order to lower the temperature of the dielectric fluid 3 and thus to improve the cooling of the electronic elements 11. Furthermore, a dielectric fluid circuit integrally disposed in the housing 12 of the cooling device is illustrated here, but it should be understood that this circuit may extend at least partially outside the housing, a connecting end piece allowing the outlet of the fluid present in the collecting tank into a duct external to the housing and another end piece allowing the return of the fluid to the condenser, for example.

According to the invention, in order to avoid an increase in the internal pressure of the housing 12 caused by undesired evaporation of the two-phase dielectric fluid 3, the cooling device 2 is provided with a pressure regulating system 4 for preventing or lessening the increase in internal pressure in the housing 12. Such undesired evaporation may take place in particular when the vehicle is stopped and therefore when the cooling fluid does not circulate in the condenser, and when an excessive temperature is identified in the housing, in particular caused by a high outside temperature.

In the first embodiment illustrated in FIG. 1, the regulating system 4 comprises a pressure sensor 42 which measures the internal pressure in the housing 12 and a control module 41 which is configured to be able to modify the configuration of the cooling circuit and in particular the circulation of the cooling fluid.

The pressure sensor 42 is disposed in the housing, in this case in the vicinity of the contact face 27 of the condenser 26, in order to measure the internal pressure in the housing, and it is configured to communicate with the control module in order to transmit the measured pressure values thereto.

The control module 41 is configured to compare the values measured with a threshold pressure value, which may in particular be equal to 1.5 bar. When the threshold pressure value is exceeded, the control module 41 has the function of generating a control instruction intended for the cooling fluid circuit 23 in order to allow the regulation of the internal pressure in the housing 12.

More particularly, when the control module 41 has detected an overpressure, a control instruction is transmitted to the cooling fluid circuit 23 of the condenser 26 in order that the cooling fluid circulates inside the circuit and can evacuate the heat energy captured from the dielectric fluid. In other words, the control instruction is intended to restart the circulation of the cooling fluid of the condenser 26, in order that the dielectric fluid 3 in the form of a vapor 31 can return to a liquid form and thus allow a reduction in the internal pressure in the housing 12.

The communication between the pressure sensor and control module, and the resultant regulating action, is implemented in particular in the event of the vehicle being stopped, and the stopping of the circulation of the cooling fluid that may result therefrom if the motor is cut.

When the control module receives information relating to such a stopped situation of the vehicle, the values measured by the pressure sensor can be requested continuously, or cyclically, at regular intervals.

The regulating action that has just been described can be stopped by monitoring of the internal pressure in the housing 12 via the pressures sensor 42. When the internal pressure decreases and passes back under the threshold pressure value, in this case 1.5 bar, the control module 41 can generate a control instruction for stopping the circulation of the cooling fluid, this circulation being able to be restarted by the control module 41 each time the threshold pressure value is exceeded within the housing 12.

The first embodiment of the cooling device 2 therefore comprises a regulating system 4 that is said to be active, meaning in this case based on the measurement of the internal pressure in the housing 12 and bringing about the condensation of the dielectric fluid 3 where necessary.

FIG. 2 is a schematic depiction of a second embodiment of the cooling device 2. This second embodiment differs from the first embodiment only with regard to the regulating system 4. Since the method for cooling the electronic elements 11 is strictly identical, reference will be made to the description of FIG. 1 with regard to this aspect of the cooling device 2.

In this second embodiment, the regulating system 4 does not include a pressure sensor and so it does not allow active regulation as described above, but rather passive, preventive regulation. As was mentioned as an option in the first embodiment, the regulating system in this case comprises a detector 43 for detecting the state of the apparatus, or of the vehicle for example, comprising this cooling device. The state detector 43 makes it possible in particular, when the cooling device is applied in a motor vehicle, to detect the stopping of the vehicle, more specifically when contact therewith is broken. The state detector 43 is configured to also detect the starting of the vehicle. During the stopping or starting of the vehicle, the state detector 43 sends a signal to the control module 41, which, just like for the first embodiment, generates a control instruction for regulating the internal pressure in the housing 12.

The regulating system also comprises a storage reservoir 45 connected to the collecting tank 25 by any line. The storage reservoir 45 is situated outside the housing 12 and only communicates with the latter via said line.

When contact with the vehicle is broken, the stoppage is detected by the state detector 43, which transmits a signal to the control module 41. The latter then controls a regulating pump 44, which draws out the dielectric fluid 3 present in the collecting tank 25 in order to direct it as far as the storage reservoir 45. As long as the vehicle is stopped, the dielectric fluid 3 is held in the storage reservoir 45. When the vehicle is restarted, the state detector 43 once again sends a signal to the control module 41, which again controls the regulating pump 44, this time in a reverse configuration in order to transfer the dielectric fluid 3 from the storage reservoir 45 to the collecting tank 25.

Thus, when the vehicle is stopped, the dielectric fluid 3 is insulated from the housing 12 and there is no risk of it evaporating under the effect of an increase in temperature and bringing about an increase in the internal pressure in the housing. When the vehicle is restarted, the dielectric fluid 3 is transferred back into the collecting tank 25 in order to be able to cool the electronic elements 11, as is described in FIG. 1.

It should be noted that the implementation of this pressure regulation involves the actuation of a pump and therefore an energy cost, albeit a minimal one. Therefore, the regulating system can be configured such that the control module 41 collects information relating to the temperature, be this the internal temperature in the housing 12 and/or the ambient temperature, so as only to activate this regulation, when the vehicle is stopped, under high temperature conditions entailing the risk of evaporation of the two-phase dielectric fluid.

Optionally, and as shown here in FIG. 2, in order that the two-phase dielectric fluid 3 is kept in the liquid state in the storage reservoir 45, the latter may be disposed within an insulating structure 46 which acts as a thermal barrier and thus prevents any evaporation within the storage reservoir 45. The dielectric fluid 3 stored in the storage reservoir 45 may also be cooled by a heat exchanger 47 in order, for the one part, to be kept in the liquid state and to avoid an undesired overpressure and, for the other part, to be at an optimal temperature for subsequently generating more effective cooling of the electronic elements 11 when the dielectric fluid 3 is transferred into the collecting tank 25. The insulating structure 46 and the cooler 47 are not inseparable. It is possible to use only one or the other with impairing the effectiveness of the regulating system 4 and/or depending on the requirements.

Therefore, the second embodiment of the cooling device 2 comprises a regulating system 4 that is said to be passive, meaning that it allows the removal of the dielectric fluid 3 from the housing 12 preventively in order to prevent it from evaporating within the latter, without this being absolutely necessary.

As illustrated in FIG. 3, the cooling device is associated with a battery pack provided with six electronic elements 11 divided into three stages of two electronic elements 11 each, each stage of electronic elements 11 having a condenser 26 vertically above it.

Each condenser 26 comprises two side walls 262 that are connected together by a top wall 261. The top wall 261 extends mainly on a plane formed by a longitudinal axis L and a transverse axis T, while the side walls 262 extend mainly on a plane formed by the longitudinal axis L and a vertical axis V, with reference to the trihedron L, V, T shown in FIG. 3. Each condenser 26 also comprises a central wall 263, extending from the top wall 261 in a manner parallel to the side walls and having identical or substantially identical dimensions to the dimensions of these side walls 262. Therefore, the condenser 26 as a whole is in the form of two Us disposed side by side, each of the Us partially framing an electronic element 11 of the stage which the condenser 26 is vertically above.

The spraying elements 22 are situated on the side walls 262 and the central wall 263 of the condenser 26, more specifically on a face of each of said walls that is oriented toward the electronic element 11, in order that the dielectric fluid can be sprayed onto the electronic elements 11. The dielectric fluid is carried to the spraying elements 22 via the dielectric fluid circuit 21, visible in relief on each of the side walls 262 and the central walls 263. For its part, the cooling fluid circuit 23 extends in the thickness of the top wall 261, from a cooling fluid inlet 231 to a cooling fluid outlet 232, each of which is situated on the top wall 261. The top wall 261 also comprises a dielectric fluid inlet 211, the outlet of dielectric fluid being effected by the spraying elements 22.

The collecting tank 25 is situated below the set of electronic elements 11 in order to collect all of the dielectric fluid, coming either directly from being sprayed onto the electronic elements 11 or brought about by the liquefying of the dielectric fluid by the condenser 26, as was described above.

Such a set of electronic elements and the associated cooling device may in particular be incorporated into a battery pack 1 as illustrated in FIG. 4, which makes it possible for example to power a hybrid or electric vehicle.

In the example illustrated, the battery pack 1, intended to be disposed under the interior of the vehicle, comprises two housings 12, each housing including within it an arrangement as shown in FIG. 3 for example.

As was mentioned above, the dielectric fluid circuit 21 is in this case arranged outside the housing, with a connecting end piece protruding from each housing 12 in the region of the collecting tank arranged inside the latter. The dielectric fluid circuit 21 is thus connected to the collecting tank in order to draw out the dielectric fluid in the form of a liquid that is deposited therein, in particular via a circulation pump 24. At the opposite end, the dielectric fluid circuit 21 is connected to a distributor plate 52 situated between the two housings 12 of the battery pack 1.

In the example illustrated, the distributor plate is configured to supply each of the stages of electronic elements with dielectric fluid.

Besides the dielectric fluid circuit 21, the battery pack 1 also comprises a connection member 51 for supplying the cooling fluid circuit of each condenser with cooling fluid. Thus, each of the housings 12 comprises two connection members 51 corresponding to a cooling fluid inlet and a cooling fluid outlet. In accordance with the description given for the dielectric fluid, the cooling fluid circulates within the distributor plate 52 so as to supply all of the condensers with cooling fluid. The connection members 51 allow each cooling fluid circuit to be connected to a cooling module, not shown in FIG. 4, which makes it possible to cool the cooling fluid after the latter has undergone heat exchanger with the dielectric fluid while it passes within each of the condensers. Each cooling fluid circuit has activation means for the circulation of the cooling fluid within this circuit, for example a valve or a pump.

The cooling device according to the first embodiment described above may in particular be employed in the battery pack illustrated in FIG. 4, by providing a pressure sensor disposed within each housing 12. The control module may in particular be disposed within one of the housings 12, or fixed to the battery pack 1, and this control module may be configured to provide a control instruction to the abovementioned activation means.

In the case of the second embodiment, it is possible to connect a channel leading to the storage reservoir from the collecting tank of each of the housings 12, via connecting end pieces that are similar to those used for connecting the dielectric fluid circuit 21 and can be seen in FIG. 4.

Of course, the invention is not limited to the examples that have just been described, and numerous modifications may be made to these examples without departing from the scope of the invention, provided that, in accordance with the invention, the cooling device comprises a system for regulating the internal pressure.

1. A device for cooling a plurality of electronic elements that are capable of releasing heat during operation for supplying electrical power to an apparatus or vehicle, said electronic elements being disposed in a housing, the device comprising:
at least one spraying element for spraying a two-phase dielectric fluid onto the electronic elements; and
a condenser provided with a cooling fluid circuit, the housing comprising a tank for collecting the dielectric fluid, the cooling device comprising a dielectric fluid circuit, which is provided with a circulation pump configured to draw the dielectric fluid from the collecting tank and is directly connected to the spraying element;
a regulating system (4) for regulating the internal pressure in the housing, the regulating system comprising a control module configured to generate a control instruction for regulating the internal pressure depending on a state of the cooling device and/or a state of the apparatus or vehicle.

2. The cooling device as claimed in claim 1, wherein the control module comprises a pressure sensor, the control module being configured to generate a control instruction for regulating the internal pressure in the housing when a value measured by the pressure sensor exceeds a threshold pressure value.

3. The cooling device as claimed in claim 2, wherein the threshold pressure value at which the pressure values measured by the pressure sensor are compared is 1.5 bar.

4. The cooling device as claimed in claim 2, wherein the control module initiates regulation of the internal pressure by generating a control instruction intended for the cooling fluid circuit associated with the condenser.

5. The cooling device as claimed in claim 1, which has a detector for detecting the state of the apparatus or vehicle, which is capable of detecting and sending to the control module information relating to the stopping or operation of the apparatus or vehicle.

6. The cooling device as claimed in claim 5, wherein the pressure regulating system comprises a storage reservoir insulated from the housing, and a regulating pump that is able to draw the dielectric fluid present in the collecting tank as far as the storage reservoir and/or to draw the dielectric fluid present in the storage reservoir as far as the collecting tank, depending on an indication provided by the detector for detecting the state of the apparatus or vehicle.

7. The cooling device as claimed in claim 6, wherein the regulating system comprises an insulating structure covering the storage reservoir.

8. The cooling device as claimed in claim 6, wherein the storage reservoir comprises a cooler.

9. A method for implementing a cooling device as claimed in claim 1, the method comprising:
determining, via the control module, at least one piece of data linked to a potential or effective increase in the internal pressure in the housing of the cooling device;
controlling the pressure regulating system to reduce the internal pressure in the housing, the control step being initiated on the basis of said data.

10. A battery pack comprising a plurality of electronic elements that are capable of releasing heat during operation and a cooling device as claimed in claim 1.
